(19) United States
(12) Patent Application Publication
(10) Pub. No.: US 2005/0162193 A1
(43) Pub. Date: Jul. 28, 2005

(54) High performance sense amplifiers

(75) Inventors: Robert F. Payne, Allen, TX (US); Bhavesh G. Bhakta, Richardson, TX (US); Sridhar Ramaswamy, Plano, TX (US); Song Wu, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/765,377

(22) Filed: Jan. 27, 2004

(51) Int. Cl. H03F 3/45

(52) U.S. Cl. 327/52

(57) ABSTRACT

A sense amplifier and associated method comprise a regenerative latch, an input differential pair of transistors coupled to the regenerative latch, and a leakage device coupled to each of the transistors comprising the input differential pair of transistors. The leakage device is adapted to maintain the input differential pair of transistors in an on state during a pre-charge phase. In other embodiments, the sense amplifier includes a clocked buffer coupled to the outputs of the regenerative latch. The clocked buffer provides additional drive current for the sense amplifier and is clocked by a clock signal that controls the regenerative latch. In yet other embodiments, the sense amplifier includes a secondary hold latch coupled to the outputs of the regenerative latch to maintain an output decision for the sense amplifier while other portions of the sense amplifier pre-charge.

### BACKGROUND OF THE INVENTION

1. Technical Field

The present subject matter relates in general to sense amplifiers and more particularly, to high speed sense amplifiers.

2. Background Information

Sense amplifiers are used in a wide variety of applications such as analog-to-digital converters and high-speed data communication receivers. While generally adequate, conventional sense amplifiers may be inadequate in high speed and other applications for one or more of the following reasons: (1) poor resolution time; (2) inability to drive large load capacitances; (3) excessive hysterisis and poor sensitivity; (4) excessive charge kickback onto the inputs of the sense amplifier during the sense amplifier's resolution phase; and (5) inability to maintain the outputs at the resolved levels during a subsequent pre-charge state. Solving one or more of the aforementioned problems, or other problems, is desirable.

### BRIEF SUMMARY

In accordance with at least some embodiments of the invention, a sense amplifier and associated method comprise a regenerative latch, an input differential pair of transistors coupled to the regenerative latch, and a leakage device coupled to each of the transistors comprising the input differential pair of transistors. The leakage device (which may be implemented as a field effect transistor) is adapted to maintain the input differential pair of transistors in an on state during a pre-charge phase.

In accordance with another embodiment of the invention, a sense amplifier and associated method comprise a regenerative latch having outputs, an input differential pair of transistors coupled to the regenerative latch, and a clocked buffer coupled to the outputs of the regenerative latch. The clocked buffer provides additional drive current for the sense amplifier and being clocked by a clock signal that controls the regenerative latch.

In accordance with another embodiment of the invention, a sense amplifier and associated method comprise a regenerative latch having outputs, an input differential pair of transistors coupled to the regenerative latch, and a secondary hold latch. The secondary latch preferably couples to the outputs of the regenerative latch to maintain an output decision for the sense amplifier while other portions of the sense amplifier pre-charge.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to.” Also, the term “couple” or “couples” is intended to mean either an indirect or direct connection. Thus, if a first device couples to a second device, that connection may be through a direct connection, or through an indirect connection via other devices and connections.

### BRIEF DESCRIPTION OF THE DRAWINGS

For a more detailed description of the preferred embodiments of the present invention, reference will now be made to the accompanying drawings, wherein:

FIG. 1 shows a sense amplifier in accordance with a preferred embodiment of the invention;

FIG. 2 shows a timing diagram associated with the operation of a sense amplifier;

FIG. 3 shows a sense amplifier in accordance with another preferred embodiment of the invention;

FIG. 4 shows a sense amplifier in accordance with another preferred embodiment of the invention;

FIG. 5 shows a sense amplifier in accordance with another preferred embodiment of the invention;

FIG. 6 shows a sense amplifier in accordance with another preferred embodiment of the invention;

FIG. 7 shows a sense amplifier in accordance with another preferred embodiment of the invention;

FIG. 8 shows a sense amplifier in accordance with another preferred embodiment of the invention; and

FIG. 9 shows a sense amplifier in accordance with another preferred embodiment of the invention.

### DETAILED DESCRIPTION OF THE PREFERRED EMBODIMENTS

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment.

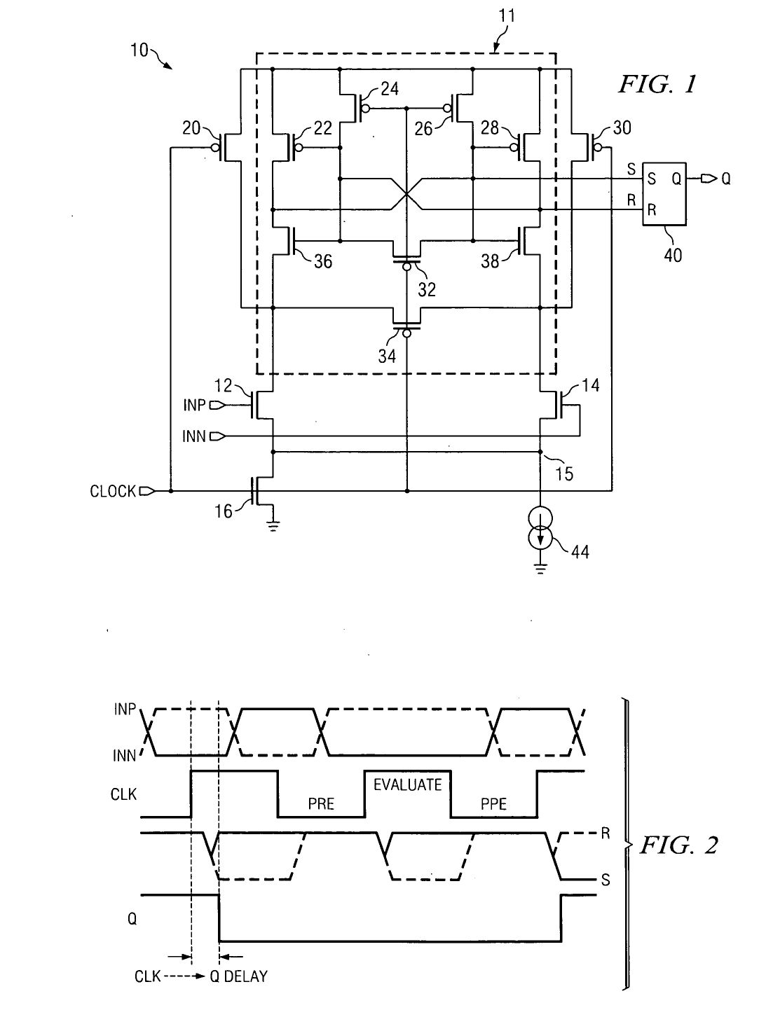

FIG. 1 shows a sense amplifier (“SA”) in accordance with an exemplary embodiment of the invention. As shown, the SA 10 comprises a regenerative latch 11 coupled to an input differential transistor pair. The regenerative latch comprises N-channel field effect transistors (“nFETs”) 36,38 and P-channel field effect transistors (“pFETs”) 20-34. The input differential transistor pair comprises nFET transistors 12 and 14 and receives differential input signals INP and INN. The nFET transistor 16 comprises a clocked current source that alternatively enables and disables the differential transistor pair 12, 14. The R and S signals represent differential output signals from the SA and are generated by the regenerative latch 11 and latched by SR latch 40.

In operation, the SA 10 preferably undergoes a “precharge” phase and an “evaluate” phase as illustrated in FIG. 2. When CLOCK is low, the R and S nodes pre-charge to a high state. That is, both R and S are high during the pre-charge phase. During the evaluate phase (clock high), the SA 10 asserts S high and R low when the INN voltage is greater than the INP voltage and asserts R high and S low when INP is greater than INN. The evaluate phase begins with each rising clock edge. A time delay called the “clock-to-Q” delay (CLK2Q) defines the time required by a sense amplifier to resolve the input differential signals (INN and INP) and generate the R and S signals following a rising clock edge.

Referring again to FIG. 1, nFET 16 is turned on and off by the CLOCK signal and accordingly causes the input differential transistor pair 12, 14 to turn on and off. During the pre-charge phase (clock low), nFET 16 is off thereby forcing input differential transistor pair 12, 14 to be off. Upon entering the evaluate phase, with the input differential pair 12,14 off, it takes time (i.e., the CLK2Q delay) to discharge node 15, turn the input differential pair 12, 14 back on to conduct current via nFET 16, and begin evaluating the differential input signals INP and INN. The SA 10 preferably includes a leakage device 44 to reduce the CLK2Q time delay. The leakage device 44 preferably comprises a field effect transistor such as an nFET with the source grounded, drain connected to node 15 and gate tied high. Other suitable types of devices or configurations of the transistors may be used in place of an nFET for this purpose. The leakage device 44 functions to maintain the input differential transistor pair 12, 14 in an “on” state even during the pre-charge phase. By keeping the input differential transistor pair on, the transistors 12, 14 can react quicker than would otherwise be possible, thereby reducing the CLK2Q time delay and decreasing the resolution time of the sense amplifier. Further, the leakage device 44 also causes the R and S differential outputs to be biased relative to each other so as to reflect the voltage difference between INP and INN during the pre-charge phase. That is, if INP is greater than INN, even during pre-charge R will be maintained at a higher voltage than S. By encouraging, during pre-charge, the differential output signals towards their ultimate evaluated voltages, the CLK2Q delay can be further reduced.

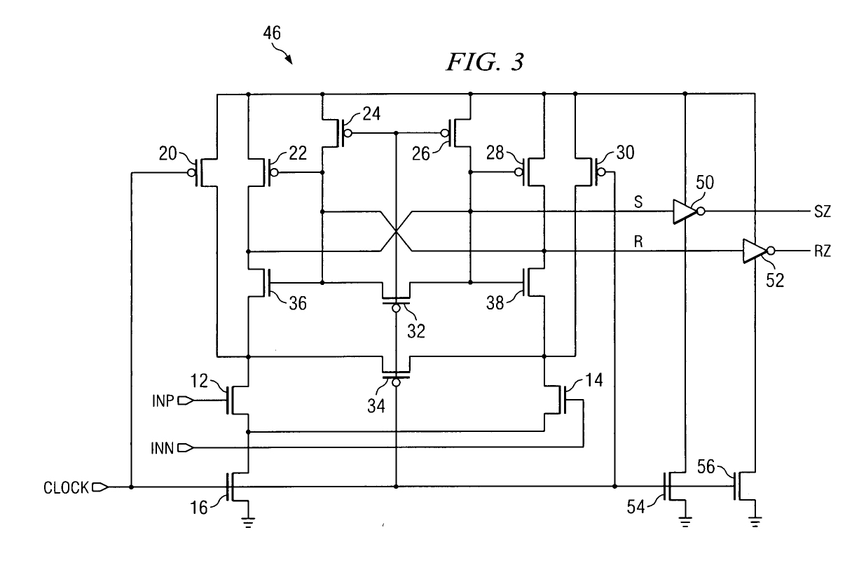

Referring now to FIG. 3, another embodiment of a sense amplifier is shown as SA 46. SA 46 includes much of the same circuitry as SA 10 of FIG. 1 and thus the description of the common circuitry is not repeated with regard to FIG. 3. SA 46 includes a pair of inverters 50 and 52 coupled to the S and R nodes, respectively. Each inverter 50, 52 can be turned on or off via control signals from gates 54 and 56 which preferably comprise nFETs. The gates 54 and 56 are turned on and off by the CLOCK signal. When CLOCK is high, the gates 54 and 56 are on thereby enabling the functionality of the inverters 50, 52. The inverters invert the logic state of the S and R signals to produce the signals labeled “SZ” and “RZ.” The inverted state of the S and R signals can be taken into account (e.g., inverted) by the device or circuitry that receives the inverted SZ and RZ signals.

When CLOCK is low (pre-charge phase), the gates 54 and 56 turn off and the inverter outputs SZ and RZ retain their previous logic levels (i.e., the logic levels present on SZ and RZ during the previous evaluate phase). The inverters also provide additional drive current so that larger loads can be driven by the sense amplifier. As such, the combination of the inverters 50, 52 and gates 54, 56 function as a clocked buffer for the S and R signals. Moreover, the latch 40 of FIG. 1 is not needed for the embodiment of FIG. 3. Without the latch 40, the speed at which valid data is generated at the SA's output is increased as described below.

The clocked inverter pair 50, 52 provides additional gain and drive capability. By including nFETs 54, 56 in series with the lower supply rail of the inverters 50, 52, it is possible to decouple the load of the sense amplifier from the core during the pre-charge stage. Because the S and R outputs are both pre-charged high, the embodiment of FIG. 3 exploits clocked gate configuration and reduces the clock loading by not using a pFET in series with the inverters' positive rails. This configuration also makes the inverters have faster rise times with smaller devices. The decoupling of the sense amplifier from the load accomplishes the following two goals.

First, the configuration of FIG. 3 prevents the load from affecting the core circuitry of the sense amplifier (i.e., the latching circuitry comprising the cross-coupled pFETs and nFETs). Many sense amplifiers are followed by an SR latch. The previous state of such a latch can have an impact on the current decision of the sense amplifier, thereby resulting in hysterisis. In some cases, the secondary latch can also kick back significant charge onto the sense amplifier inputs when the sense amplifier resolves or resets. This problem is lessened by the embodiment of FIG. 3.

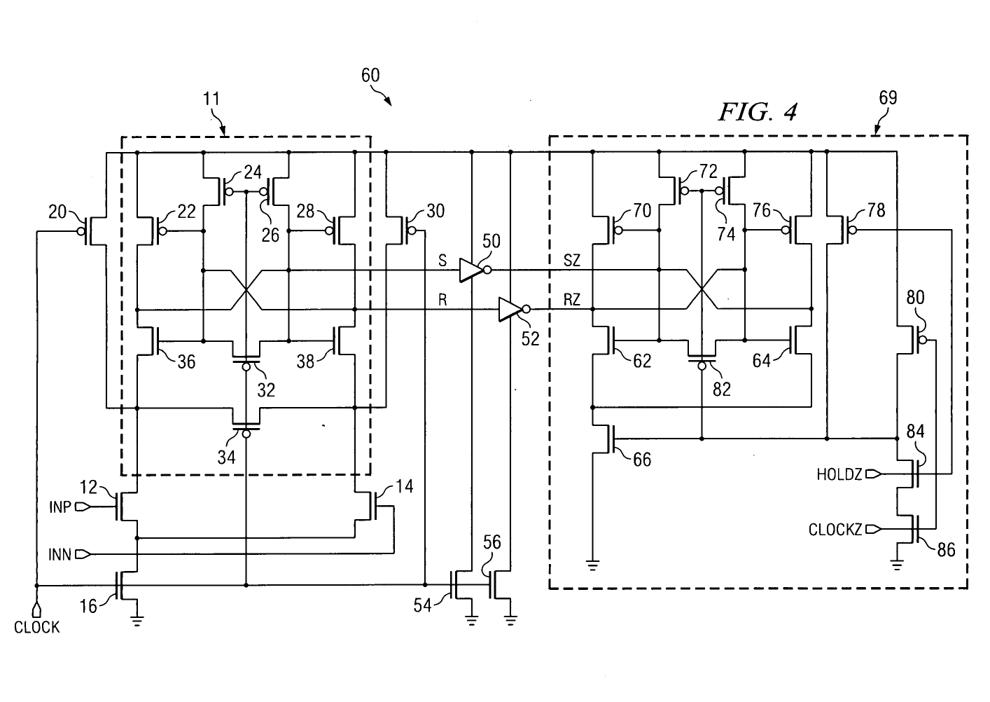

Second, the embodiment of FIG. 3 prevents the sense amplifier from prematurely resetting or overdriving the secondary latch in FIG. 4 when the sense amplifier is reset into its pre-charge state. This feature allows the secondary latch size to be minimized, reducing both area and loading on the sense amplifier.

FIG. 4 shows another embodiment of a sense amplifier comprising much of the same circuitry as in FIG. 3. The SA 60 of FIG. 4, however, further includes an additional circuit 69 that comprises nFETs 62, 64, 66, 84 and 86 and pFETs 70-82 configured as shown. The circuit 69 generally functions as a secondary “hold” latch with the regenerative latch 11 being the primary regenerative latch. As such, when the primary regenerative latch 11 resolves the input signals into voltage levels for R and S, the secondary hold latch 69 maintains and reinforces the resolved R and S voltage levels via the inverted RZ and SZ signals. The embodiment of FIG. 4 uses two clocks—CLOCK and *CLOCK (inverse of CLOCK). A rising edge of the CLOCK signal causes the input signals INP and INN to be sampled and causes the evaluate phase to begin. A rising edge of *CLOCK causes the secondary hold latch 69 to latch the resolved S and R signals from the primary latch 11. The HOLD signal allows the outputs of hold latch 69 to be maintained while the primary sense amp latch 11 continues to pre-charge to prepare to sample the next bit. Secondary hold latch 69 thus functions to maintain the previously resolved RZ and SZ signals despite the input signal levels R and S for the secondary latch 69 being removed, CLOCK going low, and another pre-charge phase being initiated which forces both S and R high as described above. In addition, secondary hold latch 69 provides additional drive capability for the SA 60 during the initial evaluate stage and continues to provide gain and drive strength even during the pre-charge phase of the primary latch 11.

The secondary hold latch 69 is useful in a variety of applications such as in a decision feedback equalizer (“DFE”) in which the sense amplifier output must be held past the pre-charge state. If the sense amplifier has not fully resolved prior to being reset, the secondary hold latch provides additional gain to fully resolve the decision into full swing complementary metal oxide semiconductor (“CMOS”) levels

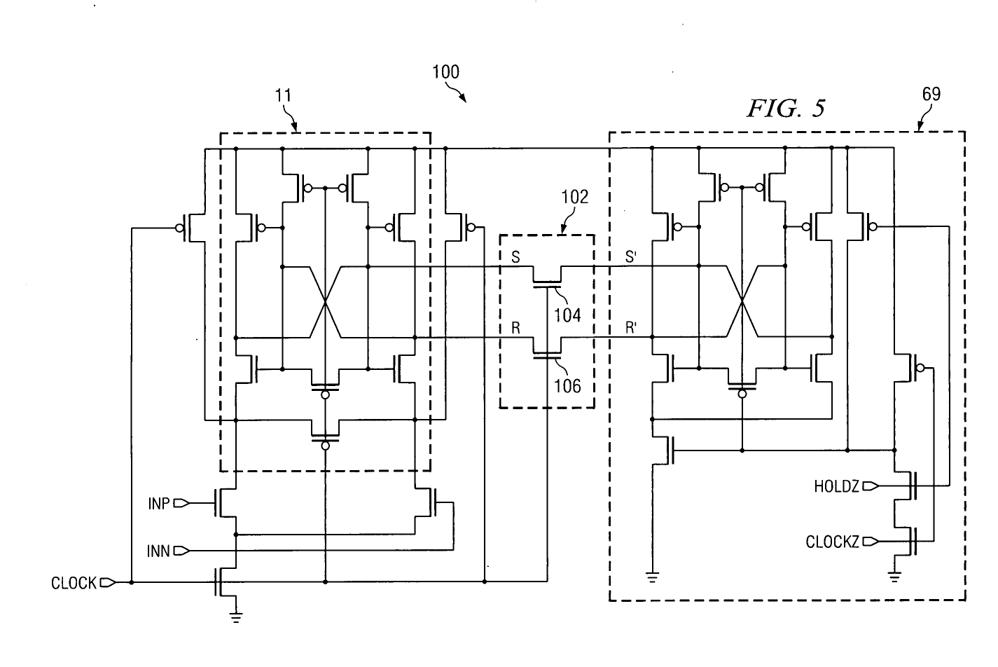

FIG. 5 shows another embodiment of a sense amplifier. SA 100 is similar to the SA 60 of FIG. 4 except that the inverters 50, 52 and associated gates 54, 56 have been replaced by a pass gate coupling and isolation circuit 102. The pass gate coupling and isolation circuit 102 preferably comprise a pair of nFETs 104 and 106, one nFET 104 for the S signal and the other NFET 106 for the R signal as shown. The gates of the nFETs 104, 106 are tied to the CLOCK signal and thus are controlled by CLOCK. When CLOCK is low, NFETS 104 and 106 are off thereby isolating the primary regenerative latch 11 from the secondary hold latch 69. When CLOCK is high, nFETs 104, 106 are on thereby coupling together the primary regenerative latch 11 and the secondary hold latch 69. When low capacitance loads need to be driven, SA 100 results in a faster CLK2Q delay time than for many other SA architectures.

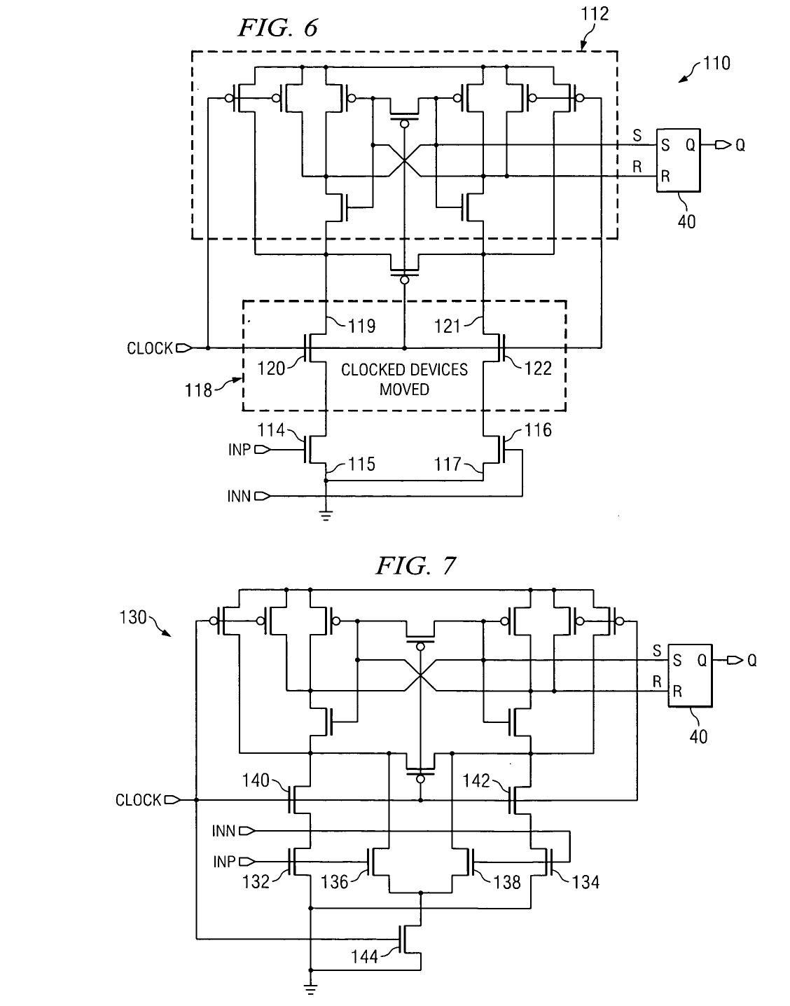

FIG. 6 shows another embodiment of a sense amplifier. The SA 110 of FIG. 6 includes a regenerative latch portion 112, a differential input transistor pair 114, 116 and a clock gating circuit 118. The clock gating circuit 118 preferably comprises a pair of nFETs 120 and 122 coupled between the drains 119, 121 of nFETs 114, 116 and the regenerative latch portion 112. This configuration contrasts that of FIG. 1, for example, in which the clock gating nFET 16 is coupled between the differential input pair and ground. In the configuration of FIG. 6, the source terminals 115, 117 of nFETs 114, 116 are tied to ground and the clock gating circuit 118 couples between the input differential pair 114, 116 and the regenerative latch portion 112. A conventional SA configuration may suffer from charge kickback which is charge that is undesirably imposed on the INP and/or INN inputs from sudden changes in drain and/or source voltages during the evaluation phase of the SA. Capacitance between the drain and gate terminals and between the source and gate terminals of the differential input transistor pair may allow charge to be kicked back on to the input signals as the source and drain voltages of transistors 114, 116 transition thereby perturbing the very signals the SA is attempting to resolve. By coupling the source terminals 115, 117 of the nFETs 114 and 116 to ground, no voltage change is experienced on the source terminals thereby eliminating charge kickback from the source-gate capacitance. Further, with CLOCK low during the pre-charge phase, both the drain terminals of nFETs 114, 116 are pulled low. Consequently, during the evaluate phase, only one of the drain terminals is forced high. Moreover, of the four source and drain terminals of the two nFETs 114, 116, only terminal (i.e., one of the drains) is permitted to change during the evaluate phase. The SA 110 of FIG. 6 thus reduces charge kickback compared to various other SA configurations. Additionally, by not including a clocked gate between the input differential pair and ground, the embodiment of FIG. 6 can achieve improved performance in the face of a relatively low common-mode range.

In FIG. 7, SA 130 comprises two pairs of differential input transistors 132, 134 and 136, 138. Transistor pair 132, 134 is clocked by the operation of clocking transistors 140, 142 which couple to the drain terminals of transistors 132, 134 as shown. The source terminals of transistors 132, 134 are grounded. Transistor pair 136, 138 is clocked by the operation of clocking transistor 144 which couples to the source terminals of transistors 136 and 138 as shown. The coordinated action of input transistors 136, 138 and clocking transistor 144 functions well (i.e., relatively fast resolution time) under high common-mode conditions, but may be plagued with undesirable levels of charge kickback as mentioned above. The coordinated action of input transistors 132, 134 and clock transistors 140, 142 reduce charge kickback, but may have slower resolution time. The combination of the two sets of input transistors and associated clocking transistors in the arrangement shown in FIG. 7 results in reduced overall resolution time over a wide common-mode range and lower charge kickback.

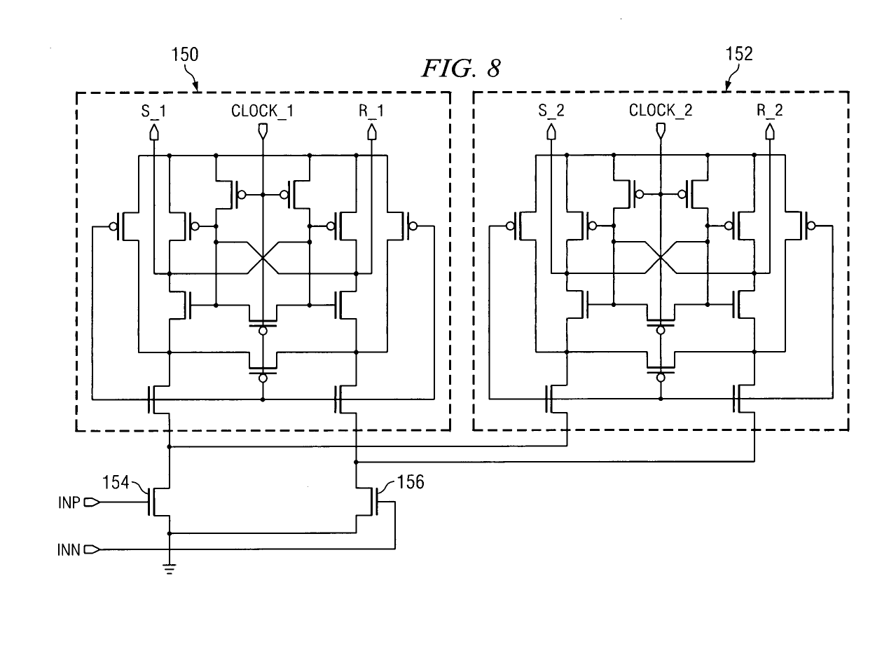

In FIG. 8, two regenerative, latching circuits 150, 152 are shown that share a single differential pair of input transistors 154, 156. Latching circuit 150 comprises a plurality of NFETs and PFETs as shown and is operated by a clock labeled CLOCK_{—}1. The differential output signals from latching circuitry 150 is shown as the S_{—}1 and R_{—}1 signals. Latching circuit 152 is operated from a separate clock signal labeled CLOCK_{—}2 and has S_{—}2 and R_{—}2 signals as output differential signals. A rising edge of CLOCK_{—}1 causes latching circuit 150 to begin its evaluate phase for the differential input signals INP and INN and a falling edge initiates the pre-charge phase. Similarly, a rising edge of CLOCK_{—}2 initiates the evaluate phase for latching circuit 152 with regard to the differential input signals INP and INN and a CLOCK_{—}2 falling edge initiates the pre-charge phase. To prevent the multiple clocked regenerative latches 150, 152 from interfering with each other, the two clocks should be non-overlapping meaning that while one latch is evaluating, the other latch is pre-charging and vice versa.

Although two latches and two clocks are illustrated in the embodiment of FIG. 8, more than two latches and clocks can be configured to share a single differential input transistor pair. The embodiment of FIG. 8 reduces loading at the inputs to the latching circuits relative to the use of a like number of individual sense amplifiers, each with its own differential input pair. In addition, individual latching circuits of separate sense amplifiers generally have random offsets associated with their differential pairs. By sharing a single differential pair between multiple latching circuits, each latching circuit shares the offset, thereby easing system implementation.

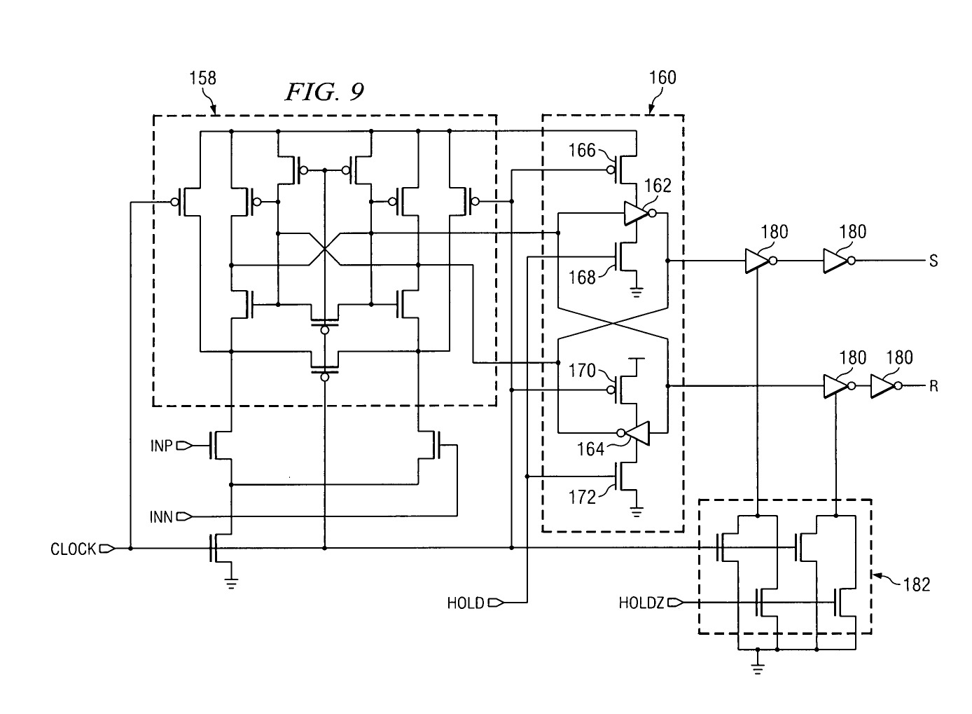

FIG. 9 shows a sense amplifier having a primary latching circuit 158 followed immediately by a secondary latching circuit 160. The secondary latching circuit 160 preferably comprises inverters 162 and 164. A pFET 166 and nFET 168 connect to inverter 162 and a pFET 170 and nFET 172 connect to inverter 164 as shown. The nFETs 168 and 172 are controlled by a HOLD signal which allows the outputs of hold latch 160 to be maintained while the primary sense amp latch 158 continues to pre-charge to prepare to sample the next bit. The nFETs 166, 170 are controlled by CLOCK. A pair of inverters 180 for each of the S and R differential output signals follows the secondary latching circuit 180 and is operated by the *HOLD signal (inverse of HOLD) via a plurality of gates 182 as shown. The embodiment of FIG. 9 exploits the fixed relationship between the CLOCK and HOLD signals to reduce the number of devices for the sense amplifier. By placing the secondary latching circuit 160 immediately after the primary latching circuit 158, the gain of the sense amplifier can be further improved. In addition, the additional inverters 180 provide even greater drive capability for large capacitive loads.

While the preferred embodiments of the present invention have been shown and described, modifications thereof can be made by one skilled in the art without departing from the spirit and teachings of the invention. For example, any one or more of the preceding sense amplifier improvements can be combined together as desired. The embodiments described herein are exemplary only, and are not intended to be limiting. Accordingly, the scope of protection is not limited by the description set out above.

1. A sense amplifier, comprising:
a regenerative latch;
an input differential pair of transistors coupled to the regenerative latch; and
a leakage device coupled to each of the transistors comprising the input differential pair of transistors, said leakage device adapted to maintain the input differential pair of transistors in an on state during a pre-charge phase.

2. The sense amplifier of claim 1 wherein the leakage device comprises a field effect transistor.

3. The sense amplifier of claim 1 further comprising a clocked buffer coupled to outputs of the regenerative latch, the clocked buffer providing additional drive current for the sense amplifier.

4. The sense amplifier of claim 1 further comprising a secondary hold latch coupled to outputs of the regenerative latch to maintain an output decision for the sense amplifier while other portions of the sense amplifier pre-charge.

5. The sense amplifier of claim 4 further comprising a pass gate coupling and isolation circuit coupled between the regenerative latch and the secondary hold latch to isolate the regenerative latch from the secondary hold latch.

6. The sense amplifier of claim 1 further comprising a pair of clocking transistors coupled to drain connections of the input differential pair of transistors and the source connections of the input differential pair of transistors is grounded.

7. The sense amplifier of claim 1 further comprising a second pair of input differential transistors, and the sense amplifier further comprises a plurality of clocking transistors, wherein a pair of the clocking transistor couples to drain connections of one pair of input differential transistors and another clocking transistor couples to the source connection of another input differential pair of transistors.

8. The sense amplifier of claim 1 further comprising a second regenerative latch, and the input differential pair of transistors is shared between both regenerative latches.

9. A sense amplifier, comprising:
a regenerative latch having outputs;
an input differential pair of transistors coupled to the regenerative latch; and
a clocked buffer coupled to the outputs of the regenerative latch, the clocked buffer providing additional drive current for the sense amplifier and being clocked by a clock signal that controls the regenerative latch.

10. The sense amplifier of claim 9 further comprising a secondary hold latch coupled to the outputs of the regenerative latch to maintain an output decision for the sense amplifier while other portions of the sense amplifier pre-charge.

11. The sense amplifier of claim 10 further comprising a pass gate coupling and isolation circuit coupled between the regenerative latch and the secondary hold latch to isolate the regenerative latch from the secondary hold latch.

12. The sense amplifier of claim 9 further comprising a pair of clocking transistors coupled to drain connections of the input differential pair of transistors and the source connections of the input differential pair of transistors is grounded.

13. The sense amplifier of claim 9 further comprising a second pair of input differential transistors, and the sense amplifier further comprises a plurality of clocking transistors, wherein a pair of the clocking transistor couples to drain connections of one pair of input differential transistors and another clocking transistor couples to the source connection of another input differential pair of transistors.

14. The sense amplifier of claim 9 further comprising a second regenerative latch, and the input differential pair of transistors is shared between both regenerative latches.

15. A sense amplifier, comprising:
a regenerative latch having outputs;
an input differential pair of transistors coupled to the regenerative latch; and
a secondary hold latch coupled to the outputs of the regenerative latch to maintain an output decision for the sense amplifier while other portions of the sense amplifier pre-charge.

16. The sense amplifier of claim 15 further comprising a pass gate coupling and isolation circuit coupled between the regenerative latch and the secondary hold latch to isolate the regenerative latch from the secondary hold latch.

17. The sense amplifier of claim 15 further comprising a pair of clocking transistors coupled to drain connections of the input differential pair of transistors and the source connections of the input differential pair of transistors is grounded.

18. The sense amplifier of claim 15 further comprising a second pair of input differential transistors, and the sense amplifier further comprises a plurality of clocking transistors, wherein a pair of the clocking transistor couples to drain connections of one pair of input differential transistors and another clocking transistor couples to the source connection of another input differential pair of transistors.

19. The sense amplifier of claim 15 further comprising a second regenerative latch, and the input differential pair of transistors is shared between both regenerative latches.

20. A method of deciding a voltage level of a communication symbol in a sense amplifier, comprising:
performing a pre-charge phase;
performing an evaluate phase in which an input symbol is resolved; and
maintaining an input differential transistor pair in an on state during the pre-charge phase.

21. The method of claim 20 further comprising generating additional drive current for the sense amplifier by operating a clocked buffer coupled to outputs of a regenerative latch in the sense amplifier.

22. The method of claim 20 further comprising maintaining an output decision for the sense amplifier while other portions of the sense amplifier pre-charge.

23. A method of deciding a voltage level of a communication symbol in a sense amplifier, comprising:
performing a pre-charge phase;
performing an evaluate phase in which an input symbol is resolved; and
generating additional drive current for the sense amplifier by operating a clocked buffer coupled to outputs of a regenerative latch in the sense amplifier.

24. The method of claim 23 further comprising maintaining an output decision for the sense amplifier while other portions of the sense amplifier pre-charge.

25. A method of deciding a voltage level of a communication symbol in a sense amplifier, comprising:
performing a pre-charge phase;
performing an evaluate phase in which an input symbol is resolved; and
maintaining an output decision for the sense amplifier while other portions of the sense amplifier pre-charge.
